(19) United States
(12) Patent Application Publication
(10) Pub. No.: US 2014/0248775 A1
(43) Pub. Date: Sep. 4, 2014

(54) CLEANING AGENT AND METHOD FOR PRODUCING SILICON CARBIDE SINGLE-CRYSTAL SUBSTRATE

(71) Applicant: ASAHI GLASS COMPANY, LIMITED, Chiyoda-ku (JP)

(72) Inventors: Iori YOSHIDA, Tokyo (JP); Katsuaki MIYATANI, Tokyo (JP)

(73) Assignee: ASAHI GLASS COMPANY, LIMITED, Chiyoda-ku (JP)

(21) Appl. No.: 14/272,778

(22) Filed: May 8, 2014

Related U.S. Application Data
(63) Continuation of application No. PCT/JP2012/080173, filed on Nov. 21, 2012.

(30) Foreign Application Priority Data
Dec. 14, 2011 (JP) 2011-272957

(51) Int. Cl. H01L 21/306

(52) U.S. Cl. CPC H01L 21/30625
USPC 438/692; 510/175

(57) ABSTRACT

The present invention provides a detergent for effectively cleaning, by a safe and simple method, a manganese component remaining on and adhered to a substrate surface, after polishing a silicon carbide single crystal substrate with a manganese compound-containing polishing agent. The present invention relates to a detergent for cleaning a silicon carbide single crystal substrate polished with a manganese compound-containing polishing agent, the detergent including at least one of ascorbic acid and erythorbic acid, in which the detergent has a pH of 6 or less.

### TECHNICAL FIELD

The present invention relates to a detergent and a method for producing a silicon carbide single crystal substrate, and more particularly to a detergent for cleaning a silicon carbide single crystal substrate after polished using a manganese compound-containing polishing agent and a method for producing a silicon carbide single crystal substrate in which cleaning after polishing is performed using the detergent.

### BACKGROUND OF THE INVENTION

Silicon carbide (SiC) semiconductors are higher in a breakdown electric field, saturated drift velocity of electrons and thermal conductivity than silicon semiconductors, so that research and development for realizing power devices capable of high-speed operation at a higher temperature than the conventional silicon devices has been made using the silicon carbide semiconductors. Among others, attention is drawn to development of high-efficiency switching elements used in power sources for driving motors of two-wheeled electric vehicles, electric cars, hybrid cars and the like. In order to realize such power devices, silicon carbide single crystal substrates having smooth surfaces and high cleanliness for forming high-quality silicon carbide single crystal layers by epitaxial growth are necessary.

In recent years, in the production of the silicon carbide single crystal substrates, chemical mechanical polishing (hereinafter sometimes referred to as CMP) technology has been studied as a method for forming extremely smooth substrate surfaces. The CMP is a method of converting a surface of a material to be processed to an oxide or the like by utilizing a chemical reaction such as oxidation and removing the formed oxide by using an abrasive having a lower hardness than the material to be processed, thereby polishing the surface. This method has an advantage of being able to form an extremely smooth surface without producing strain on the surface of the material to be processed.

As a polishing agent for the above-mentioned CMP, there has been known a colloidal silica-containing polishing composition having a pH of 4 to 9 (for example, see Patent Document 1). However, in the polishing of the silicon carbide single crystal substrate with this polishing composition, there has been a problem that the polishing rate is low to decrease productivity. In order to improve productivity by high-speed polishing, there has been proposed a polishing agent having a stronger chemical action. Specifically, the high polishing rate is realized by an acidic polishing agent containing a silica abrasive and permanganate ion (for example, see Patent Document 2). Further, there has been proposed a neutral to alkaline polishing agent in which manganese dioxide is used as an abrasive, and the high polishing rate is realized (for example, see Patent Document 3).

In general, contaminations such as polishing agent-derived abrasive residues or heavy metals are generated on and adhered to a substrate surface after polishing by CMP. These contaminations have been known to cause malfunction or performance degradation of devices, and cleaning of the substrate after polishing becomes indispensable.

As a method for cleaning a silicon carbide single crystal substrate after polishing, there has hitherto been widely used a cleaning method using at high temperature a highly concentrated chemical obtained by adding a strong acid (sulfuric acid, hydrochloric acid) or an alkali (ammonia) and further hydrofluoric acid to hydrogen peroxide as a base, so-called RCA (Radio Corporation of America) cleaning (for example, see Non-Patent Document 1 and Non-Patent Document 2).

However, in the RCA cleaning method described in Non-Patent Document 1 and Non-Patent Document 2, strongly acidic or strongly alkaline highly concentrated hydrogen peroxide is used at high temperature, and highly toxic hydrofluoric acid is used. Accordingly, not only there is a problem in workability, but also corrosion resistance around a cleaning apparatus and an exhaust facility are required. Further, a rinsing step with a large amount of pure water is required after the cleaning treatment, and there has been a problem that the environmental load is also large.

In recent years, to such problems, there has been required a simple and effective cleaning method capable of suppressing the environmental load and equipment cost, which has higher safety and better workability, is capable of simplifying facilities around the cleaning apparatus, and requires no rinsing with a large amount of pure water. Specifically, there has been required a cleaning method using a low concentrated chemical (for example, hydrogen peroxide or the like) under weakly acidic to weakly alkaline conditions at room temperature and not using highly toxic hydrofluoric acid.

However, in the above-mentioned method using the low concentrated chemical under weakly acidic to weakly alkaline conditions, the cleaning effect has been insufficient for the silicon carbide single crystal substrate that is low in chemical reactivity and high in chemical resistance compared to the silicon substrate. In particular, as described in Patent Document 2 and Patent Document 3, in the simple cleaning method using low concentrated hydrogen peroxide under weakly acidic to weakly alkaline conditions at room temperature, the effect of removing metal contamination due to adhesion of the manganese component has been insufficient for the silicon carbide single crystal substrate after polished with the polishing agent containing the compound of manganese as a heavy metal at a high concentration. For this reason, there has been a problem that the substrate after cleaning cannot be used for the device preparation.

### BACKGROUND ART DOCUMENT

### Patent Document

Patent Document 1: JP-A-2005-117027
Patent Document 2: JP-A-2009-238891
Patent Document 3: JP-A-2011-122102

### Non-Patent Document

Non-Patent Document 1: RCA Review, p. 187, June 1970
Non-Patent Document 2: “Research Report of Business Commissioned by New Energy and Industrial Technology Development Organization in 2003, Research on SiC Semiconductor/Device Commercialization and Diffusion Strategy”, p. 40, Research & Development Association for Future Electron Devices

### SUMMARY OF THE INVENTION

### Problems that the Invention is to Solve

The invention has been made in order to solve such problems, and an object thereof is to provide a detergent for effectively cleaning, by a safe and simple method, a manganese component remaining on and adhered to a substrate surface, after polishing a silicon carbide single crystal substrate with a manganese compound-containing polishing agent showing a high polishing rate. Further, another object thereof is to provide a method for producing a silicon carbide single crystal substrate having no metal contamination due to manganese and the like by performing cleaning with such a detergent.

### Means for Solving the Problems

The detergent in the present invention is the detergent for cleaning a silicon carbide single crystal substrate polished with a manganese compound-containing polishing agent, the detergent comprising at least one of ascorbic acid and erythorbic acid, wherein the detergent has a pH of 6 or less.

In the detergent of the invention, it is preferred that the polishing agent contains at least one selected from the group consisting of manganese dioxide, dimanganese trioxide and a permanganate ion. Moreover, it is preferred that the detergent has a pH of 5 or less. Furthermore, it is preferred that a total content ratio of the ascorbic acid and the erythorbic acid to the whole detergent is from 0.1% by mass to 50% by mass.

The method for producing a silicon carbide single crystal substrate of the invention is the method for producing a silicon carbide single crystal substrate comprising: a polishing step of polishing a silicon carbide single crystal substrate using a manganese compound-containing polishing agent; and a cleaning step of cleaning the silicon carbide single crystal substrate using a detergent after the polishing step, wherein the detergent of the above-mentioned invention is used as said detergent.

In the method for producing a silicon carbide single crystal substrate of the invention, it is preferred that the polishing agent contains at least one selected from the group consisting of manganese dioxide, dimanganese trioxide and a permanganate ion. Moreover, it is preferred that the detergent has a pH of 5 or less. Furthermore, it is preferred that in the detergent, a total content ratio of the ascorbic acid and the erythorbic acid to the whole detergent is from 0.1% by mass to 50% by mass.

Incidentally, in the invention, “manganese compound” shall be considered to include not only a manganese-containing covalent compound having no electric charge, but also a compound ion having electric charge.

### Advantage of the Invention

According to the detergent of the invention, cleaning is performed while dissolving a manganese-containing component (hereinafter also referred to as a manganese component) such as the manganese compound adhered to the silicon carbide single crystal substrate, and it can be effectively removed, by cleaning the silicon carbide single crystal substrate after polished with the manganese compound-containing polishing agent having a high polishing rate, using a liquid containing at least one of ascorbic acid and erythorbic acid and having a pH of 6 or less.

Then, according to the method for producing a silicon carbide single crystal substrate of the invention comprising a cleaning step with such a detergent, the manganese component such as the above-mentioned manganese compound adhered to the silicon carbide single crystal substrate can be effectively removed, so that polishing with the manganese compound-containing polishing agent having a high polishing rate becomes possible. Then, the silicon carbide single crystal substrate having no metal contamination due to manganese and the like can be obtained, and the device having excellent characteristics can be prepared. Further, the detergent of the invention is adjusted to a wide pH range of pH 6 or less, and contains ascorbic acid or the like at a relatively low concentration and no highly toxic component, so that there can be significantly reduced the load of workability and the exhaust facility and the like around the cleaning apparatus and the load of the rinsing step requiring a large amount of pure water.

### BRIEF DESCRIPTION OF THE DRAWINGS

FIG. 1 is a view showing one example of a cleaning apparatus that can be used in an embodiment of the invention.

### MODE FOR CARRYING OUT THE INVENTION

Embodiments of the invention are described below.

A method for producing a silicon carbide single crystal substrate of an embodiment of the invention comprises a polishing step of polishing a silicon carbide single crystal substrate using a manganese compound-containing polishing agent and a cleaning step of cleaning the silicon carbide single crystal substrate after the polishing step, using a detergent. Then, a cleaning liquid containing at least one of ascorbic acid and erythorbic acid and having a pH of 6 or less, the detergent of the invention, is used as said detergent.

First, the method for producing a silicon carbide single crystal substrate of the invention is described, and then, the detergent used in the cleaning step in this production method is described.

### [Polishing Step]

The method for producing a silicon carbide single crystal substrate of the invention comprises the polishing step of performing polishing using the manganese compound-containing polishing agent.

### (Polishing Agent)

The manganese compound contained in the polishing agent is preferably at least one selected from the group consisting of manganese dioxide, dimanganese trioxide and a permanganate ion. Manganese dioxide and dimanganese trioxide are preferably contained in the polishing agent as an abrasive. The average particle size of manganese dioxide and dimanganese trioxide contained as the abrasive is preferably from 0.05 μm to 3.0 μm, and more preferably from 0.1 μm to 1.0 μm. When the average particle size is less than 0.05 μm, the polishing rate to the silicon carbide single crystal substrate is low, and when the average particle size exceeds 3.0 μm, there is a problem that the abrasive has poor dispersibility to easily cause the occurrence of scratches on a substrate surface. In this specification, the average particle size is measured by a laser diffraction-scattering type particle size distribution measuring method, and means D₅₀ of the 50% diameter in the integrated fraction on the volumetric basis.

Further, the content ratio (concentration) of manganese dioxide and dimanganese trioxide contained as the abrasive to the whole polishing agent is preferably from 0.1% by mass to 30% by mass, and more preferably from 1% by mass to 20% by mass, in the total of manganese dioxide and dimanganese trioxide. When the content ratio (concentration) of manganese dioxide and dimanganese trioxide contained is less than 0.1% by mass in total, the polishing rate to the silicon carbide single crystal substrate is low, and when it exceeds 30% by mass, dispersion of the abrasive becomes difficult, and there is a problem of increased cost.

Of the manganese compounds contained in the polishing agent, the permanganate ion functions as an oxidizing agent for a silicon carbide single crystal to improve the CMP rate of the silicon carbide single crystal substrate. Supply sources of the permanganate ion preferably include permanganates such as potassium permanganate and sodium permanganate. When the polishing agent contains the permanganate ion, it may contain particles of the above-mentioned manganese dioxide and dimanganese trioxide, silica, ceria, alumina, zirconia, titania, iron oxide, chromium oxide and the like as the abrasive. The average particle size of the abrasive and the content ratio (concentration) thereof contained are preferably within the same range as in the case of the above-mentioned manganese dioxide and dimanganese trioxide.

Further, when the polishing agent contains the permanganate ion, it may contain substantially no abrasive, and can be used as a polishing liquid. The content ratio (concentration) of the permanganate ion contained in the polishing agent is preferably from 0.01% by mass to 7.5% by mass, and more preferably from 0.05% by mass to 5% by mass, regardless of the presence or absence of the abrasive. When the content ratio (concentration) of the permanganate ion contained is less than 0.01% by mass, the oxidation reaction of the substrate surface becomes insufficient to decrease the polishing rate. When it exceeds 7.5% by mass, the permanganate ion is deposited as a salt, and the salt deposited might cause the occurrence of flaws and the like on the substrate surface.

The polishing agent used in the polishing step in the embodiment of the invention preferably contains water as a dispersion medium. Water is a medium for stably dispersing the abrasive, and for dispersing and dissolving the above-mentioned permanganate ion and optional ingredients described later, which are added as needed. Although there is no particular limitation on water, preferred are pure water, ultrapure water and ion-exchanged water (deionized water) from the viewpoints of an influence on blended ingredients, contamination with impurities and an influence on pH or the like.

Further, the polishing agent may contain a pH adjuster, a lubricant, a dispersing agent and the like. The pH adjusters include acids or basic compounds. As the acid, there can be used an inorganic acid such as nitric acid, sulfuric acid, phosphoric acid or hydrochloric acid, and an organic acid such as a saturated carboxylic acid such as formic acid, acetic acid, propionic acid or butyric acid, a hydroxy acid such as lactic acid, malic acid or citric acid, an aromatic carboxylic acid such as phthalic acid or salicylic acid, a dicarboxylic acid such as oxalic acid, malonic acid, succinic acid, glutaric acid, adipic acid, fumaric acid or maleic acid, an amino acid or a heterocyclic carboxylic acid. The use of nitric acid and phosphoric acid is preferred, and the use of nitric acid is particularly preferred. As the basic compound, there can be used ammonia, lithium hydroxide, potassium hydroxide, sodium hydroxide, a quaternary ammonium compounds such as tetramethylammonium, or an organic amine such as monoethanolamine, ethylethanolamine, diethanolamine or propylenediamine. The use of potassium hydroxide and sodium hydroxide is preferred, and potassium hydroxide is particularly preferred.

The dispersing agent is one added for stably dispersing the abrasive and the like in the dispersion medium such as pure water. Further, the polishing agent moderately adjusts polishing stress developed with an object to be polished to make stable polishing possible. As the dispersing agent and the lubricant, there can be used an anionic, cationic, nonionic or amphoteric surfactant, a polysaccharide, a water-soluble polymer or the like. As the surfactant, there can be used one having an aliphatic hydrocarbon group or an aromatic hydrocarbon group as a hydrophobic group, with one or more of a bonding group such as an ester, an ether or an amide and a linking group such as an acyl or alkoxyl group introduced into the hydrophobic group, or one having a carboxylic acid, a sulfonic acid, a sulfuric acid ester, a phosphoric acid, a phosphoric acid ester or an amino acid as a hydrophilic group. As the polysaccharide, there can be used alginic acid, pectin, carboxymethylcellulose, curdlan, pullulan, xanthan gum, carrageenan, gellan gum, locust bean gum, gum arabic, tamarind, psyllium or the like. As the water-soluble polymer, there can be used polyacrylic acid, polyvinyl alcohol, polyvinyl pyrrolidone, polymethacrylic acid, polyacrylamide, polyaspartic acid, polyglutamic acid, polyethyleneimine, polyallylamine, polystyrenesulfonic acid or the like. When the dispersing agent and the lubricant are used, the content ratios thereof contained are each preferably within a range of 0.001 to 5% by mass based on the whole polishing agent, respectively.

### (Polishing Method)

As a method for polishing the silicon carbide single crystal substrate, which is the object to be polished, using the above-mentioned manganese compound-containing polishing agent, preferred is a polishing method of bringing a face to be polished of the object to be polished and a polishing pad into contact with each other while supplying the polishing agent to the polishing pad, and performing polishing by relative movement between both. Incidentally, the “face to be polished” is a face to be polished of the object to be polished, and means, for example, a surface thereof.

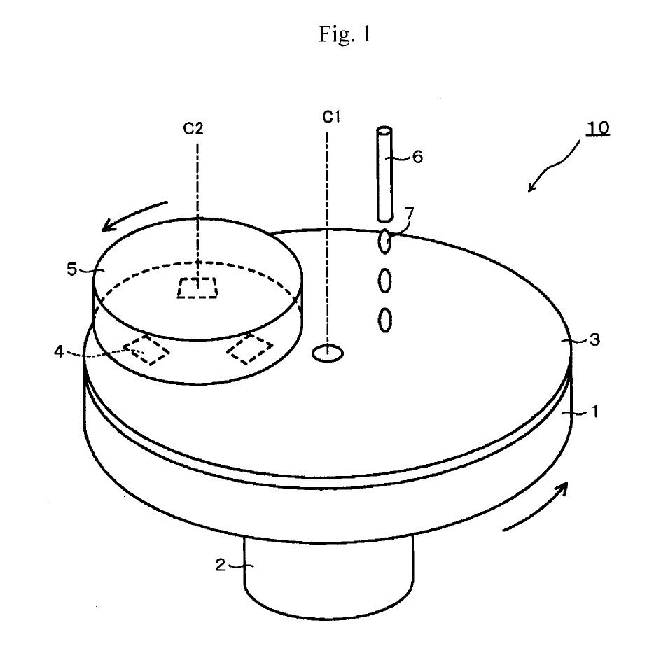

In this polishing method, any conventionally known polishing machine can be used as a polishing machine. Although one example of a polishing machine usable in the embodiment of the invention is shown in FIG. 1, the polishing machine used in the polishing step of the invention should not be construed as being limited to one having such a structure.

In the polishing machine 10 shown in FIG. 1, a polishing surface plate 1 is provided in a state supported rotatably around a perpendicular shaft center C1 thereof, and this polishing surface plate 1 is driven for rotation by a surface plate driving motor 2 in a direction indicated by an arrow in the figure. A known polishing pad 3 is attached to an upper surface of this polishing surface plate 1.

On the other hand, in a position eccentric from the shaft center C1 on the polishing surface plate 1, a substrate holding member (carrier) 5 for holding an object 4 to be polished, such as a SiC single crystal substrate, on an under surface thereof by adsorption or by using a holding frame or the like is supported rotatably around a shaft center C2 thereof and movably in a direction of the shaft center C2. This substrate holding member 5 is constituted so as to be rotated in a direction indicated by an arrow by a work driving motor not shown or by the rotational moment transferred from the above-mentioned polishing surface plate 1. The object 4 to be polished is held on the under surface of the substrate holding member 5, namely a surface facing the above-mentioned polishing pad 3. The object 4 to be polished is pressed on the polishing pad 3 with a predetermined load.

Further, in the vicinity of the substrate holding member 5, a dropping nozzle 6 and the like are provided, and a polishing agent 7 (hereinafter also referred to as a polishing liquid) of the invention sent from a tank not shown is supplied onto the polishing surface plate 1.

In polishing with such a polishing machine 10, the object 4 to be polished that is held on the substrate holding member 5 is pressed on the polishing pad 3, while supplying the polishing liquid 7 from the dropping nozzle 6 and the like to a surface of the polishing pad 3, in a state where the polishing surface plate 1 and the polishing pad 3 attached thereto, and the substrate holding member 5 and the object 4 to be polished that is held on the under surface thereof, are each driven for rotation around each shaft center by the surface plate driving motor 2 and the work driving motor, respectively. The polished surface of the object 4 to be polished, namely the surface facing the polishing pad 3, is chemically mechanically polished thereby.

The substrate holding member 5 may perform not only rotational movement, but also linear movement. Further, the polishing surface plate 1 and the polishing pad 3 may not be one that performs rotational movement, and for example, may be one that moves in one direction by a belt system.

Although there is no particular limitation on polishing conditions in such a polishing machine 10, it is possible to increase polishing pressure by applying the load to the substrate holding member 5 to press it to the polishing pad 3, thereby improving the polishing rate. The polishing pressure is preferably from about 5 to 80 kPa, and from the viewpoints of uniformity of the polishing rate in the polished surface, flatness and prevention of polishing defects such as scratches, more preferably from about 10 to 50 kPa. The numbers of rotations of the polishing surface plate 1 and the substrate holding member 5 are preferably from about 50 to 500 rpm, but are not limited thereto. Further, the amount of the polishing liquid 7 supplied is appropriately adjusted and selected depending on the constituent material of the polished surface, the composition of the polishing liquid, the above-mentioned polishing conditions and the like.

As the polishing pad 3, there can be used one composed of common non-woven fabric, foamed polyurethane, a porous resin, a non-porous resin or the like. Further, in order to promote supply of the polishing liquid 7 to the polishing pad 3 or to allow a specific amount of the polishing liquid 7 to remain in the polishing pad 3, there may be performed groove processing of a grid form, a concentric form, a spiral form or the like on the surface of the polishing pad 3. Further, polishing may be performed while performing conditioning of the surface of the polishing pad 3 by bringing a pad conditioner into contact with the surface of the polishing pad 3, as needed.

### [Cleaning Step]

In the method for producing a silicon carbide single crystal substrate of the invention, the silicon carbide single crystal substrate is polished using the above-mentioned manganese compound-containing polishing agent having a high polishing rate, and thereafter, the silicon carbide single crystal substrate after polishing is cleaned using the detergent containing at least one of ascorbic acid and erythorbic acid and having a pH of 6 or less. The manganese component such as the manganese compound adhered to the silicon carbide single crystal substrate in the polishing step can be dissolved and effectively removed by cleaning the silicon carbide single crystal substrate using the above-mentioned detergent.

### (Detergent)

The detergent of the invention contains at least one of ascorbic acid and erythorbic acid and has a pH of 6 or less.

The reason why the detergent containing ascorbic acid and/or erythorbic acid shows a high cleaning-removal effect to the manganese component such as the manganese compound adhered to the silicon carbide single crystal substrate is not sure. However, it is considered that the high cleaning effect is exhibited by reducing the manganese compound and the like adhered to the surface of the silicon carbide single crystal substrate after polishing to a manganese ion having a more soluble valence, because ascorbic acid and erythorbic acid have sufficient reducing ability. Further, ascorbic acid and erythorbic acid prevent re-adhesion of the manganese ion eluted in the liquid by forming complexes with the manganese ion, thereby being able to effectively discharge the manganese component. Accordingly, also from this point, it is considered that the high cleaning effect is exhibited.

The content ratio (concentration) of ascorbic acid and erythorbic acid to the whole detergent is preferably from 0.1% by mass to 50% by mass, more preferably from 0.25% by mass to 25% by mass, and still more preferably from 0.5% by mass to 10% by mass, in the total of ascorbic acid and erythorbic acid. When the content ratio of ascorbic acid and erythorbic acid contained to the whole detergent is less than 0.1% by mass in total, the cleaning effect becomes insufficient, and when it exceeds 50% by mass, dissolution of ascorbic acid and erythorbic acid becomes insufficient, and precipitates might remain on the substrate surface.

The detergent of the invention preferably contains water as a solvent for ascorbic acid and erythorbic acid. Examples of the water include deionized water, ultrapure water, charged ion water, hydrogen water, ozone water and the like. Incidentally, the water has a function of controlling fluidity of the detergent of the invention, so that the content thereof can be appropriately set depending on intended cleaning characteristics. It is preferred that the content of the water is usually adjusted to 50 to 99.5% by mass of the whole detergent.

The detergent containing at least one of ascorbic acid and erythorbic acid, which is the embodiment of the invention, has the cleaning effect above a certain level to the manganese compound and the like within a wide pH range of pH 6 or less of the liquid. However, the pH of the detergent is preferably 5 or less, and more preferably 3 or less. When the pH of the detergent exceeds 6, the cleaning effect to the manganese compound and the like becomes insufficient.

The detergent of the invention may contain a cleaning aid. The cleaning aids include, for example, surfactants, polysaccharides and water-soluble polymers for lowering the surface tension and acids having a buffering effect for stably maintaining the pH.

As the cleaning aid for lowering the surface tension, there can be used, for example, an anionic, cationic, nonionic or amphoteric surfactant, a polysaccharide, a water-soluble polymer or the like. As the surfactant, there can be used one having an aliphatic hydrocarbon group or an aromatic hydrocarbon group as a hydrophobic group, with one or more of a bonding group such as an ester, an ether or an amide and a linking group such as an acyl group or an alkoxyl group introduced into the hydrophobic group, or one having a carboxylic acid, a sulfonic acid, a sulfuric acid ester, a phosphoric acid, a phosphoric acid ester or an amino acid as a hydrophilic group. As the polysaccharide, there can be used alginic acid, pectin, carboxymethylcellulose, curdlan, pullulan, xanthan gum, carrageenan, gellan gum, locust bean gum, gum arabic, tamarind, psyllium or the like. As the water-soluble polymer, there can be used polyacrylic acid, polyvinyl alcohol, polyvinyl pyrrolidone, polymethacrylic acid, polyacrylamide, polyaspartic acid, polyglutamic acid, polyethyleneimine, polyallylamine, polystyrenesulfonic acid or the like.

Further, the acids having the buffering effect for stably maintaining the pH include, for example, acids having a pKa of 2 to 5 and having one or more carboxylic acid groups, specifically citric acid. However, many other organic acids can be used.

### (Cleaning Method)

In the cleaning step, it is preferred that the above-mentioned detergent is brought into direct contact with the silicon carbide single crystal substrate to perform cleaning. Methods for bringing the detergent into direct contact with the substrate include, for example, dip cleaning of filling the detergent in a cleaning tank and putting the substrate therein, a method of spraying the detergent from a nozzle to the substrate, scrub cleaning using a sponge made of polyvinyl alcohol or the like, and the like. The detergent of the invention can be adapted to any of the above-mentioned methods. However, dip cleaning used in combination with ultrasonic cleaning is preferred because effective cleaning can be performed.

In the cleaning step, the time for which the detergent is in contact with the silicon carbide single crystal substrate is preferably 30 seconds or more. By adjustment to 30 seconds or more, the sufficient cleaning effect can be obtained.

In the cleaning step, the temperature of the detergent may be room temperature, or it may be heated to about 40 to 80° C. and used. However, it is preferred to be adjusted to 80° C. or less. By adjusting the temperature of the detergent to 80° C. or less, ascorbic acid can be prevented from the occurrence of thermal decomposition. Further, in the structure of the apparatus, when the detergent approaches a temperature of near 100° C., pH control by evaporation of water becomes difficult. It is therefore preferred to be adjusted to 80° C. or less.

According to such a cleaning step, cleaning is performed while dissolving the manganese component such as the manganese compound adhered to the silicon carbide single crystal substrate, and it can be effectively removed, by cleaning the silicon carbide single crystal substrate after polished using the manganese compound-containing polishing agent having a high polishing rate, using the liquid containing at least one of ascorbic acid and erythorbic acid and having a pH of 6 or less. Then, in the cleaning method using the detergent of the invention, the manganese compound removal rate equivalent to or higher than that in the conventional RCA cleaning (for example, a manganese removal rate of 99% or more) can be realized.

Further, according to the method for producing a silicon carbide single crystal substrate of the invention comprising the cleaning step with the detergent of the invention, the manganese component such as the manganese compound adhered to the substrate can be effectively removed in the cleaning step, so that polishing with the polishing agent having the manganese compound showing a high polishing rate becomes possible. Further, the silicon carbide single crystal substrate having cleanliness equivalent to or higher than that in the RCA cleaning can be obtained by the safe and simple method, and a semiconductor device having good characteristics can be prepared.

### EXAMPLE

The invention is described in detail below by examples and comparative examples, but the invention should not be construed as being limited to these examples. Examples 1 to 5, Example 10 and Example 11 are examples of the invention, and Examples 6 to 9 and Example 12 are comparative examples.

### Examples 1 to 12

### (1) Preparation of Detergent

Detergents having the compositions shown in Table 1 were prepared as shown below.

In Examples 1 to 4 and Examples 8 to 11, the respective additives shown in the same Table were added to pure water to attain the content ratios (concentrations) shown in the same Table, followed by stirring for about 5 minutes to dissolve the additives. In Examples 5 to 7, the respective additives shown in Table 1 were added to pure water to attain the content ratios (concentrations) shown in the same Table, followed by stirring for about 5 minutes to dissolve the additives, and thereafter, potassium hydroxide was added thereto as a pH adjuster to perform adjustment to the predetermined pH values shown in Table 1. In Example 12, hydrogen peroxide was added to pure water to attain the content ratio (concentration) shown in Table 1, followed by stirring for about 5 minutes, and thereafter, hydrochloric acid was added thereto as a pH adjuster to perform adjustment to pH 3. Incidentally, the pH values of the respective detergents were measured at 25° C. using pH 81-11 manufactured by Yokogawa Electric Corporation.

TABLE 1

| | | Con- | Con- | |
|---|---|---|---|---|
| | | centra- | centra- | |
| | | tion | tion | |
| | | of | of | |
| | | Additive | Additive | pH of |
| Example | Kind of Additive | (mass %) | (mmol/kg) | Detergent |
| 1 | Erythorbic Acid | 0.10 | 6 | 3 |
| 2 | Erythorbic Acid | 1.00 | 57 | 2.6 |
| 3 | Erythorbic Acid | 5.00 | 284 | 2.3 |
| 4 | Erythorbic Acid | 10.00 | 568 | 2.2 |
| 5 | Erythorbic Acid | 1.00 | 57 | 5 |
| 6 | Erythorbic Acid | 1.00 | 57 | 8 |
| 7 | Erythorbic Acid | 1.00 | 57 | 10 |
| 8 | Citric Acid | 1.09 | 57 | 2.2 |
| 9 | Oxalic Acid | 0.72 | 57 | 2.1 |
| 10 | Ascorbic Acid | 1.00 | 57 | 2.6 |
| 11 | Ascorbic Acid:Erythorbic | 1.00 | 57 | 2.6 |
| | Acid Mass Ratio (1:1) | | | |
| 12 | Hydrogen Peroxide | 1.00 | 294 | 3 |

### (2) Preparation of Substrate to Be Cleaned

As a silicon carbide single crystal substrate used in a cleaning test, there was used a 4H—SiC substrate preliminarily polished using a diamond abrasive, in which a 3-inch diameter principal surface (0001) was within 4°±0.5° to the C axis. This substrate was polished with a polishing liquid under polishing conditions shown below, and used as a substrate to be cleaned for the cleaning test.

### (Polishing Liquid)

Pure water was added to potassium permanganate, followed by stirring using an impeller for 10 minutes. Then, nitric acid was gradually added as a pH adjuster to this liquid with stirring to adjust the pH so as to fall within a range of 2.0 to 3.0. The thus-obtained liquid having a content ratio (concentration) of potassium permanganate contained of 1.58% by mass was used as the polishing liquid.

### (Polishing Conditions)

As a polishing machine, there was used a small one-side polishing machine manufactured by MAT Inc. As a polishing pad, SUBA800-XY-groove (manufactured by Nitta Haas Inc.) was used, and conditioning of the polishing pad was performed using a diamond disc and a brush before polishing. Further, polishing was performed for 30 minutes, setting the supply rate of the polishing liquid to 25 cm³/min, the number of rotations of a polishing surface plate to 90 rpm, and the polishing pressure to 5 psi (34.5 kPa).

### (3) Cleaning Test

Each substrate after polished with the above-mentioned polishing liquid was immersed in each detergent of Examples 1 to 12, and subjected to an ultrasonic treatment for 5 minutes. Thereafter, the substrate taken out of the detergent was rinsed with pure water, and dried with air. Then, in order to examine the amount of manganese remaining on a surface of each substrate after cleaning, each substrate was immersed in a mixed solution obtained by mixing hydrochloric acid (36% by mass), pure water and a 30% hydrogen peroxide solution at a volume ratio of 4.5:4.5:1, at 70° C. or more for about 1 hour. Then, the mixed solution after immersion was analyzed with an ICP mass spectrometer, and the mass of manganese element detected in the mixed solution (hereinafter indicated as the manganese amount) was measured.

### (4) Judgment of Cleaning Effect

The substrate not cleaned after subjected to the polishing treatment with the above-mentioned polishing liquid (hereinafter referred to as the uncleaned substrate) was immersed in the above-mentioned mixed solution of hydrochloric acid and hydrogen peroxide, and the manganese amount in the mixed solution was detected and measured with the ICP mass spectrometer. Then, the manganese removal rate was calculated using the following equation from the manganese amount detected and measured from the uncleaned substrate and the manganese amount detected and measured from the substrate subjected to the cleaning treatment with each detergent, and judgment of the cleaning effect was performed. The calculation results of the manganese removal rate are shown in Table 2.

Manganese removal rate=(detected manganese amount of uncleaned substrate−detected manganese amount of cleaned substrate)/(detected manganese amount of uncleaned substrate)×100(%)

Incidentally, when the manganese removal rate thus calculated is 99% or more, it can be said to have high cleaning performance equivalent to or more than that in the RCA cleaning, as the cleaning method for obtaining the silicon carbide single crystal substrate for the semiconductor device.

That is to say, when the RCA cleaning is performed at a high temperature of 70° C. or more to the silicon carbide single crystal substrate after polishing, using a strongly acidic cleaning liquid having a pH of less than 1, in which 36% by mass of hydrochloric acid, 30% by mass of hydrogen peroxide and pure water are mixed at a volume ratio of 1:1:5, the manganese removal rate becomes 99% or more. Then, the use of the substrate thus subjected to the RCA cleaning allows to obtain the device having good operating characteristics. It is therefore preferred that the cleanliness of the substrate having no effect on device operation in later steps is judged based on the value of the manganese removal rate (99% or more) by the RCA cleaning method.

TABLE 2

| Example | Manganese Removal Rate (%) |
|---|---|
| 1 | 99.0 |
| 2 | 99.6 |
| 3 | 99.6 |
| 4 | 99.6 |
| 5 | 99.4 |
| 6 | 96.1 |
| 7 | 94.2 |
| 8 | 93.7 |
| 9 | 98.5 |
| 10 | 99.8 |
| 11 | 99.8 |
| 12 | 96.9 |

From Table 2, it is seen that in Examples 1 to 5, Example 10 and Example 11 in which cleaning has been performed with the detergents of pH 6 or less containing at least one of ascorbic acid and erythorbic acid, the manganese removal ratio is as high as 99% or more to have high cleaning performance equal to that in the RCA cleaning. In contrast, in Example 6 and Example 7, cleaning has been performed using the detergents having a pH outside the range of the invention, although containing erythorbic acid, so that the manganese removal rate becomes less than 99% to show that the cleaning effect is not sufficient. Further, also in Example 8 and Example 9 in which cleaning has been performed with the detergents containing citric acid or oxalic acid in place of ascorbic acid, it has been confirmed that the manganese removal rate results in being less than 99% to show that the cleaning effect is low. Also in Example 12 in which cleaning has been performed with the detergent containing hydrogen peroxide, the manganese removal rate is less than 99% to show that the cleaning effect is insufficient.

Like this, in the examples of the invention, the cleanliness equivalent to or higher than that in the RCA cleaning can be realized to the silicon carbide single crystal substrate by the safe and simple method.

While the present invention has been described in detail with reference to specific embodiments thereof, it will be apparent to one skilled in the art that various changes and modifications can be made therein without departing from the spirit and scope thereof.

Incidentally, the present application is based on Japanese Patent Application No. 2011-272957 filed on Dec. 14, 2011, and the contents are incorporated herein by reference.

### INDUSTRIAL APPLICABILITY

According to the detergent of the invention, the manganese component such as the manganese compound adhered to the silicon carbide single crystal substrate after polished with the manganese compound-containing polishing agent having a high polishing rate can be effectively cleaned and removed. Then, the silicon carbide single crystal substrate having no metal contamination due to manganese and the like can be obtained, and the semiconductor device having excellent operating characteristics can be prepared. Further, according to the detergent of the invention, there can be significantly reduced the load of workability and the exhaust facility and the like around the cleaning apparatus and the load of the rinsing step requiring a large amount of pure water.

### DESCRIPTION OF REFERENCE NUMERALS AND SIGNS

1: Polishing surface plate
2: Surface plate driving motor
3: Polishing pad
4: Object to be polished
5: Substrate holding member
6: Dropping nozzle
7: Polishing agent
10: Polishing machine

1. A detergent for cleaning a silicon carbide single crystal substrate polished with a manganese compound-containing polishing agent, the detergent comprising at least one of ascorbic acid and erythorbic acid,
wherein the detergent has a pH of 6 or less.

2. The detergent according to claim 1, wherein the polishing agent contains at least one selected from the group consisting of manganese dioxide, dimanganese trioxide and a permanganate ion.

3. The detergent according to claim 1, having a pH of 5 or less.

4. The detergent according to claim 2, having a pH of 5 or less.

5. The detergent according to claim 1, wherein a total content ratio of the ascorbic acid and the erythorbic acid to the whole detergent is from 0.1% by mass to 50% by mass.

6. The detergent according to claim 2, wherein a total content ratio of the ascorbic acid and the erythorbic acid to the whole detergent is from 0.1% by mass to 50% by mass.

7. The detergent according to claim 3, wherein a total content ratio of the ascorbic acid and the erythorbic acid to the whole detergent is from 0.1% by mass to 50% by mass.

8. The detergent according to claim 4, wherein a total content ratio of the ascorbic acid and the erythorbic acid to the whole detergent is from 0.1% by mass to 50% by mass.

9. A method for producing a silicon carbide single crystal substrate comprising:
a polishing step of polishing a silicon carbide single crystal substrate using a manganese compound-containing polishing agent; and
a cleaning step of cleaning the silicon carbide single crystal substrate using a detergent after the polishing step,
wherein the detergent according to claim 1 is used as said detergent.

10. The method for producing a silicon carbide single crystal substrate according to claim 9, wherein the polishing agent contains at least one selected from the group consisting of manganese dioxide, dimanganese trioxide and a permanganate ion.

11. The method for producing a silicon carbide single crystal substrate according to claim 9, wherein the detergent has a pH of 5 or less.

12. The method for producing a silicon carbide single crystal substrate according to claim 10, wherein the detergent has a pH of 5 or less.

13. The method for producing a silicon carbide single crystal substrate according to claim 9 wherein in the detergent, a total content ratio of the ascorbic acid and the erythorbic acid to the whole detergent is from 0.1% by mass to 50% by mass.

14. The method for producing a silicon carbide single crystal substrate according to claim 10 wherein in the detergent, a total content ratio of the ascorbic acid and the erythorbic acid to the whole detergent is from 0.1% by mass to 50% by mass.

15. The method for producing a silicon carbide single crystal substrate according to claim 11 wherein in the detergent, a total content ratio of the ascorbic acid and the erythorbic acid to the whole detergent is from 0.1% by mass to 50% by mass.

16. The method for producing a silicon carbide single crystal substrate according to claim 12 wherein in the detergent, a total content ratio of the ascorbic acid and the erythorbic acid to the whole detergent is from 0.1% by mass to 50% by mass.
